(19) United States
(12) Patent Application Publication
(10) Pub. No.: US 2026/0262167 A1
(43) Pub. Date: Sep. 3, 2026

(54) PACKAGE FOR POWER MODULE

(71) Applicant: Renesas Electronics America Inc., Milpitas, CA (US)

(72) Inventors: Zhizheng LIU, Fremont, CA (US); Haiyu ZHANG, Sunnyvale, CA (US); Sri Ganesh A THARUMALINGAM, Fremont, CA (US); Mark Alan KWOKA, Palm Bay, FL (US); Yonggoo EOM, Danville, CA (US)

(73) Assignee: Renesas Electronics America Inc., Milpitas, CA (US)

(21) Appl. No.: 19/491,257

(22) PCT Filed: Jun. 6, 2024
(86) PCT No.: PCT/US2024/032715

§ 371 Date: Dec. 8, 2025

Related U.S. Application Data
(60) Provisional application No. 63/506,431, filed on Jun. 6, 2023.

(51) Int. Cl. H05K 1/181; H05K 1/02; H10D 1/20; H10W 90/10; H10W 90/20

(52) U.S. Cl. CPC H05K 1/181; H05K 1/0203; H10D 1/20; H10W 90/10; H10W 90/291; H05K 2201/09227; H05K 2201/1003; H05K 2201/10166; H05K 2201/10515; H05K 2201/10651

(57) ABSTRACT

An electronic system comprising a printed circuit board having a conductive trace that is coupled to a voltage output is provided. A voltage regulator is disposed on the printed circuit board that includes a voltage regulator phase output terminal. Additionally, the electronic system comprises an inductor module coupled with the voltage regulator. The inductor module includes an inductor core and an inductor segment having a first and a second end, where the inductor segment first end is connected to the voltage regulator phase output terminal and the inductor segment second end is connected to the printed circuit board conductive trace. The inductor segment is configured to pass through and wrap around at least a portion of the inductor core and the voltage regulator is configured to transfer heat through the voltage regulator phase output terminal to the inductor segment and the inductor module.

### CROSS-REFERENCE TO RELATED APPLICATION

This application is based upon and claims the benefit under 35 U.S.C. 119(e) of U.S. Patent Application No. 63/506,431 filed on Jun. 6, 2023, and titled INDUCTOR LEAD AS THERMAL DISSIPATION PIPE, the entire disclosure of which is incorporated herein by reference in its entirety.

### BACKGROUND

The present disclosure relates in general to semiconductor devices and packages, more particularly, to voltage regulator systems, including trans-inductor voltage regulator (TLVR) systems.

Voltage regulators, such as buck converters and boost converters, can be used for converting an input voltage to an output voltage having a different voltage level. A buck converter, or step-down converter, can convert the input voltage into a lower voltage. A boost converter, or step-up converter, can convert the input voltage into a higher voltage. A buck-boost converter can step up or step down the input voltage. A voltage regulator can include a pair of power transistors that can be turned on and off alternately by a pulse width modulated (PWM) control signal. A duty cycle of the PWM control signal can define an output voltage of the voltage converter. When the voltage converter is connected to a load, the load can demand a specific amount of power by drawing a specific amount of current, and the voltage converter can perform the voltage conversion to generate the output voltage that can deliver the power demanded by the load.

One example voltage regulator architecture is a multiphase voltage regulator which includes a plurality of phases. Each phase includes a power stage and an inductor. All phases share a controller and the output capacitors. The controller generates PWM signals to the power stages to control the power transistors to turn on and off. The duty cycle of the PWM signals can be adjusted by the controller to obtain the target output voltage. The phases are connected in parallel, and the turn-on of the phases can be interleaved to reduce the output current ripple, output voltage ripple and input current ripple to improve system performance. Heat build-up in electronic components in voltage regulators may affect the reliability of the voltage regulator, or may cause damage and could shorten component life.

### SUMMARY

In one embodiment, an electronic system is generally described. The electronic system can include a printed circuit board having a conductive trace that is coupled to a voltage output. The voltage regulator can be disposed on the printed circuit board and having a voltage regulator phase output terminal that is accessible on a top surface of the voltage regulator. The electronic system can further include an inductor module coupled with the voltage regulator. The inductor module can include an inductor core and an inductor segment having a first end and a second end. The inductor segment first end can be connected to the voltage regulator phase output terminal. The inductor segment second end can be connected to the printed circuit board conductive trace. The inductor segment can pass through and wrap around at least a portion of the inductor core. The voltage regulator can be configured to transfer heat through the voltage regulator phase output terminal to the inductor segment and inductor module.

In one embodiment, an electronic system is generally described. The electronic system can include a printed circuit board having a first conductive trace and a second conductive trace. The electronic system can further include a first voltage regulator disposed on the printed circuit board and having a first voltage regulator phase output terminal that is accessible on a top surface of the first voltage regulator. The electronic system can further include a second voltage regulator disposed on the printed circuit board and having a second voltage regulator phase output terminal that is accessible on a top surface of the second voltage regulator. The electronic system can further include an inductor module coupled with the first voltage regulator and the second voltage regulator and spanning at least a portion of a first top surface portion of the first voltage regulator and a second top surface portion of the second voltage regulator. The inductor module can include an inductor core and an inductor segment having a first end and a second end. The inductor segment first end can be connected to the first voltage regulator phase output terminal and the second voltage regulator phase output terminal. The inductor segment second end can be connected to the printed circuit board conductive trace. The inductor segment can pass through and wrap around at least a portion of the inductor core. The first voltage regulator and the second voltage regulator can be configured to transfer heat through the first voltage regulator phase output terminal and the second voltage regulator phase output terminal to the inductor segment and inductor module.

In one embodiment, a semiconductor module is generally described. The semiconductor module can include a wiring substrate. The semiconductor module can further include a first module component mounted on the wiring substrate including a first MOSFET, a second MOSFET coupled in series to the first MOSFET, a first driver IC for controlling a first gate of the first MOSFET and a second gate of the second MOSFET. The semiconductor module can further include a second module component mounted on the wiring substrate, and arranged next to the first module component including a third MOSFET, a fourth MOSFET coupled in series to the third MOSFET, a second driver IC for controlling a third gate of the third MOSFET and a fourth gate of the fourth MOSFET. The semiconductor module can further include an inductor module including a sealing body having an upper surface, a lower surface opposite the upper surface, and a side surface between the upper surface and the lower surface. The inductor module can include a first inductor segment having a main portion, a first inductor portion protruded from the main portion, and coupled with a first output terminal of the first module component, and extending in a first direction that can be a horizontal direction. The first output terminal can be coupled with each of a source of the first MOSFET and a drain of the second MOSFET. The inductor module can include a second inductor portion protruded from the main portion, and coupled with a second output terminal of the second module component, and extending in the first direction, the second output terminal being coupled with each of a source of the third MOSFET and a drain of the fourth MOSFET. The inductor module can include an output portion protruded from the main portion, coupled with a terminal of the wiring substrate, and extending in a second direction that is a vertical direction crossing to the first direction. The inductor component is arranged on each of the first module and the second module.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a system that can include at least one inductor package for power module in one embodiment.

FIG. 2 illustrates an example arrangement of an inductor package for power module in one embodiment.

FIG. 3 illustrates a cross-sectional view of module with an inductor package for power module in one embodiment.

FIG. 4 illustrates a bottom view of module with an inductor package for power module in one embodiment.

FIG. 5 illustrates positions of various connection points of the system of FIG. 1 with an inductor package for power module in one embodiment.

FIG. 6 illustrates a cross-sectional view of module with an inductor package for power module in one embodiment.

FIG. 7 illustrates a three-dimensional view of a power module with an inductor package in one embodiment.

### DETAILED DESCRIPTION

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

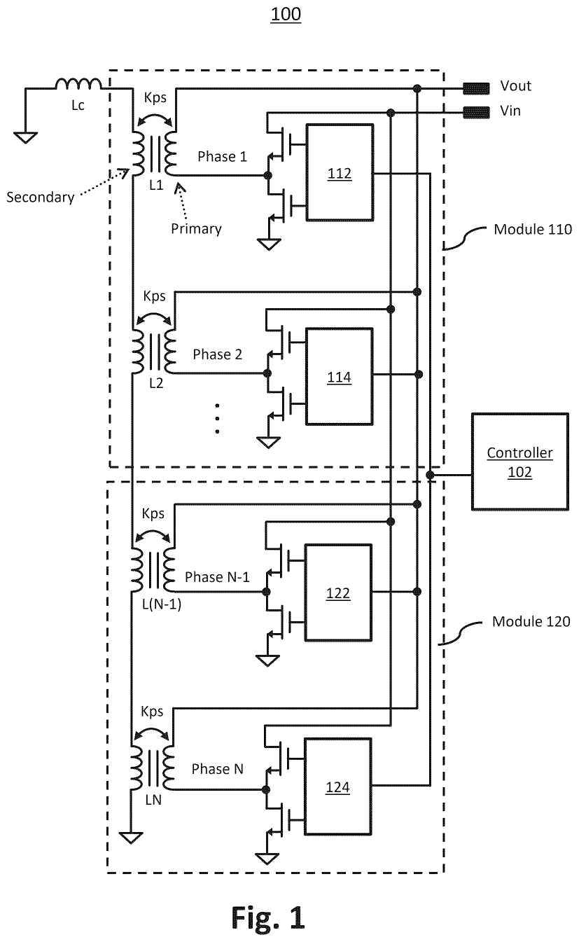

FIG. 1 illustrates an example of a system that can include a package for power module in one embodiment. System 100 in FIG. 1 can be a voltage regulation system, according to a non-limiting example. As used herein, the terms block, module, circuit, system and the like may refer to various hardware, firmware, and software elements, or a combination thereof.

System 100 can include at least a module 110 and a module 120. Each one of module 110 and module 120 can be a dual-phase trans-inductor voltage regulator (TLVR) module. Each one of modules 110, 120 can include two TLVRs, hence implementing a dual-phase TLVR module. Each TLVR in modules 110, 120 can be considered as a phase of a multiphase voltage regulator. In the example embodiment shown in FIG. 1, N power stages are shown, module 110 can include two power stages and module 120 can include two power stages as well. Each power stage can include a pair of power transistors, also referred to as a phase, and a driver configured to drive the pair of power transistors. Each pair of power transistors can include a high-side (HS) transistor and a low-side (LS) transistor, where the HS transistor can be connected between an input voltage and the LS transistor and the LS transistor can be connected between the HS transistor and ground (GND). In one embodiment, the power transistors can be metal-oxide semiconductor field-effect transistors (MOSFETs). In the example shown in FIG. 1, module 110 can include two power stages corresponding to Phase 1 and Phase 2 and module 120 can include two power stages corresponding to Phase N-1 and Phase N. Each phase can be switched to produce a voltage at a switch node (e.g., common node) between the pair of power transistors. Phase 1 and Phase 2 can be driven by driver integrated circuits (ICs) 112, 114, respectively. Phase N-1 and Phase N can be driven by driver ICs 122, 124, respectively. System 100 can include a controller (e.g., microcontroller) configured to provide control signals (e.g., pulse width modulation (PWM) signals) to driver ICs 112, 114, 122, 124 for driving the power stages of system 100.

In an aspect, some applications may require voltage regulators to have relatively fast dynamic response during load transients to satisfy the output voltage ripple requirements. TLVRs can provide relatively fast dynamic response during the load transients of multiphase voltage regulators as TLVR structures leverage TLVR inductors to replace the output inductors in traditional multiphase voltage regulators. In an aspect, a TLVR inductor can be a 1:1 transformer that includes a primary winding and a secondary winding. In the example shown in FIG. 1, system 100 can include a plurality of TLVR inductors L1 to LN for the N phases, where each TLVR inductor includes a primary winding and a secondary winding. The coupling of a TLVR inductor can be realized by connecting the secondary winding of all TLVR inductors. As shown in the example in FIG. 1, the secondary windings of TLVR inductors L1 to LN are connected. Due to the coupling effect, the output current of all phases can ramp up or down at the same time once the duty cycle of one phase of system 100 changes to respond to the load transient, thus providing relatively fast dynamic response at load transients.

Conventionally, semiconductor packages for a power stage or a phase of a voltage regulation system can include one inductor module per power stage. To be described in more detail below, an inductor module that can be arranged over two power stages is disclosed. By way of example, module 110 can include one inductor module implementing L1, L2 and module 120 can include another inductor module implementing L(N-1) and LN. The inductor module described herein can occupy relatively less mounting area when compared to conventional power stage packages. Further, the arrangement of the inductor package described herein can provide a thermal pipe to facilitate cooling, hence reducing heat build-up to improve the reliability of system 100, prevent component damages and prolong component life of components in system 100.

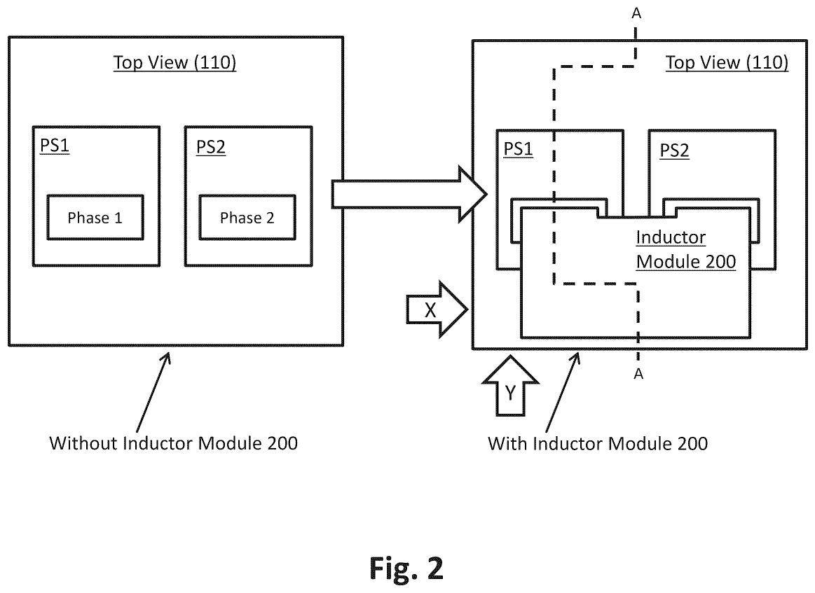

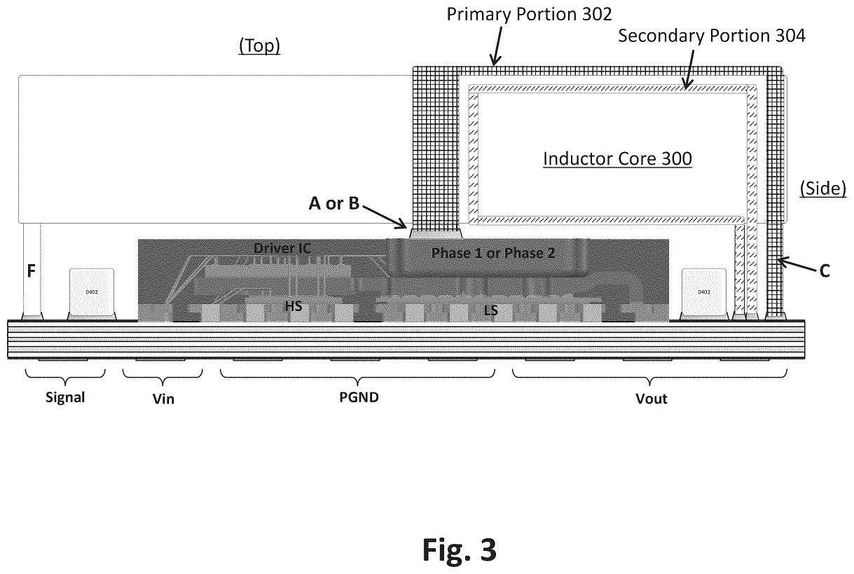

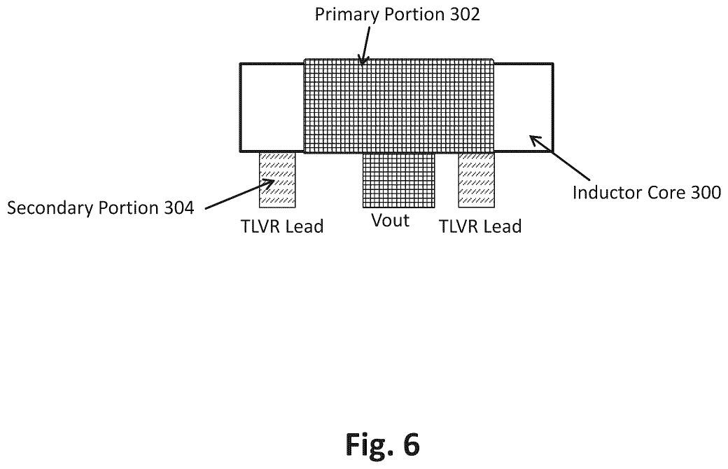

FIG. 2 illustrates an example arrangement of an inductor package for power module in one embodiment. Descriptions of FIG. 2 can reference components shown in FIG. 1. In an example embodiment shown in FIG. 2, top views of module 110 before and after disposing an inductor module 200 are shown. As shown in FIG. 2, inductor module 200 can be dispose on top of power stages PS1, PS2, where PS1 is the power stage including Phase 1 and PS2 is the power stage including Phase 2. In one embodiment, inductor module 200 can be disposed on top of Phase 1 and Phase 2, and can wrap around at least the top surface and a side surface of power stages PS1, PS2. Further details of the wrap around and positioning of inductor module 200, such as a cross-sectional view (X direction) along a path A-A in FIG. 2, will be shown and described below in FIG. 3. A side view from the Y direction will be shown and described below in FIG. 6. Note that the arrangement of inductor module 200 shown in FIG. 2 can be applicable to module 120 as well, where inductor module 200 can be disposed on top of phases and/or power stages of module 120.

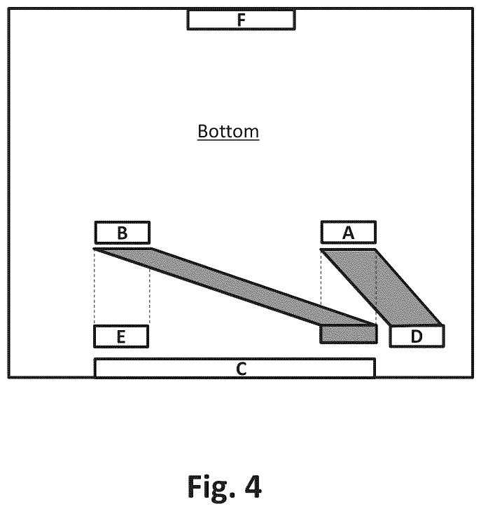

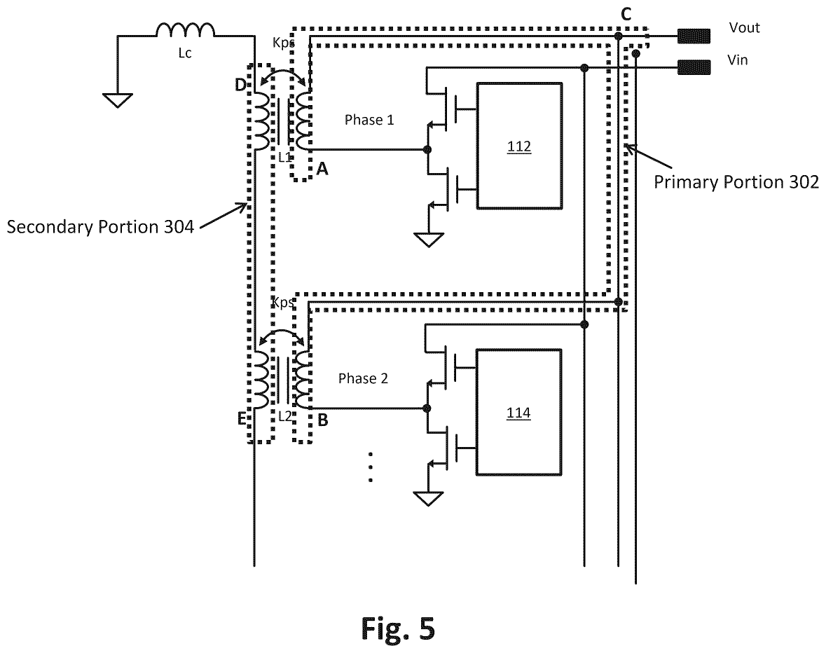

FIG. 3 illustrates a cross-sectional view of module with an inductor package for power module in one embodiment. Descriptions of FIG. 3 can reference components shown in FIG. 1 and FIG. 2. In an example shown in FIG. 3, inductor module 200 can be disposed on module 110. Inductor module 200 can include an inductor core, a primary portion 302 and a secondary portion 304. Primary portion 302 can include the primary windings of the TLVR inductors L1, L2 of module 110 shown in FIG. 1. Secondary portion 304 can include the secondary windings of the TLVR inductors L1, L2 of module 110 shown in FIG. 1. Primary portion 302 and secondary portion 304 can be conductive traces. A plurality of identifiers A, B, C, D, E shown in FIG. 3 will be described in more detail below with respect to at least FIG. 4 and FIG. 5.

FIG. 4 illustrates a bottom view of module with an inductor package for power module in one embodiment. Descriptions of FIG. 4 can reference components shown in FIG. 1 to FIG. 3. In an example shown in FIG. 4, a bottom view of module 110 with inductor module 200 disposed on at least the top of module 110 is shown. In FIG. 4, a plurality of locations A, B, C, D and E are shown. Position A can be a bottom view of identifier A shown in FIG. 3 if the cross-sectional view of FIG. 3 shows Phase 1 (e.g., TLVR lead). Position B can be a bottom view of identifier B shown in FIG. 3 if the cross-sectional view of FIG. 3 shows Phase 2 (e.g., TLVR lead). Position C can be a bottom view of identifier C shown in FIG. 3. Position D can be a bottom view of a connection point between secondary winding of L1 and Lc (e.g., phase lead) shown in FIG. 1. Position E can be a bottom view of a connection point between secondary winding of L2 and secondary winding of a next phase (e.g., phase lead).

FIG. 5 illustrates positions of various connection points of the system of FIG. 1 with an inductor package for power module in one embodiment. Descriptions of FIG. 5 can reference components shown in FIG. 1 to FIG. 4. In an example shown in FIG. 5, the locations of identifiers A, B, C, D, E in system 100 corresponding to positions A, B, C, D, E in the bottom view of FIG. 4 are shown. As shown in FIG. 5, the inductor module 200 can be disposed as a single inductor module implementing both TLVR inductors L1 and L2.

FIG. 6 illustrates a cross-sectional view of module with an inductor package for power module in one embodiment. Descriptions of FIG. 6 can reference components shown in FIG. 1 and FIG. 5. A side view, in the Y direction according to FIG. 2, after disposing inductor module 200 is shown in FIG. 6. As shown in FIG. 6, primary portion 302 can wrap around and be visible on a side of inductor core 300. Secondary portion 304 can be connected to TLVR leads, such as identifiers A and B shown in FIG. 3 to FIG. 5.

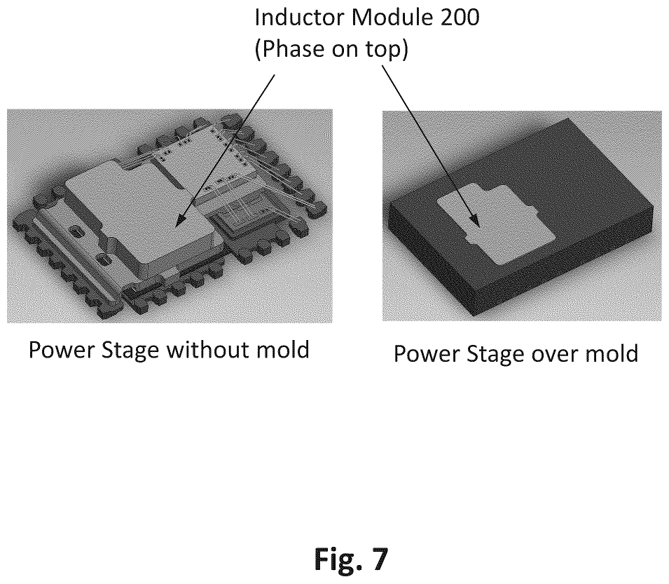

FIG. 7 illustrates a three-dimensional view of a power module with an inductor package in one embodiment. Descriptions of FIG. 7 can reference components shown in FIG. 1 and FIG. 6. Three-dimensional (3D) views of a power stage without mold and over mold are shown in FIG. 7. As shown in FIG. 7, after disposing inductor module 200 on a power stage, the inductor module can be exposed on a top surface (with the phase nodes being on top). The exposure of the inductor module 200 on the top surface can provide cooling to reduce heat build-up to improve the reliability of the power stage, prevent component damages and prolong component life of components in the power stage. In one embodiment, to dispose inductor module 200, the inductor phase leads (e.g., A and B in FIG. 3 to FIG. 5) can be soldered on power stage copper slug. Further, as shown in FIG. 3, the inductor Vout lead can be connected or soldered to Vout pads directly (e.g., C). Disposing a single inductor module over two power stages can also provide relatively small power module size and also incur relatively lower cost. Further, as shown in the present disclosure, second PCB board is not necessary thus copper clips between PCBs can be eliminated as well.

According to one example, an electronic system (system 100) may be described as a Trans-Inductor Voltage Regulator (Single TLVR) and may include a printed circuit board having a conductive trace that is coupled to a voltage output (Vout), a voltage regulator (e.g., power stage) disposed on the printed circuit board and having a voltage regulator phase output terminal (PH, such as Phase 1 to Phase N) that is accessible on a top surface of the voltage regulator; and an inductor module (inductor module 200) coupled with the voltage regulator or power stage. As used herein, the printed circuit board (PCB) is used generally and may refer to various other single-layer or multi-layer board-like configurations for connecting various electronic components, may include a substrate board with fine or coarse pitch features, may include a foundation board upon which a PCB is mounted, or the like. The inductor module (inductor module 200) may have an inductor core and an inductor segment having a first end (primary portion 302) and a second end (secondary portion 304), the inductor segment first end may be connected to the voltage regulator phase output terminal. The inductor segment second end may be connected to the printed circuit board conductive trace, and the inductor segment may be configured to pass through and wrap around at least a portion of the inductor core (inductor core 300). In this manner, the inductor segment and the inductor core may form an output inductor. The voltage regulator may be configured to transfer heat through the voltage regulator phase output terminal to the inductor segment and inductor module. In this manner, heat from the voltage regulator may be dissipated through convection and radiation from the top and side surfaces of both the inductor segment and inductor module, and possibly also dissipated by conduction to the printed circuit board.

According to this example, the conductive trace may have a conductive trace first end (primary portion 302) and a conductive trace second end (secondary portion 304) where the conductive trace second end is disposed under a bottom portion of the voltage regulator between the bottom of the voltage regulator and the printed circuit board so that the inductor segment and the conductive trace surround at least an end portion of the voltage regulator body. The inductor core (inductor core 300) may be positioned or disposed relative to the voltage regulator in one of (a) entirely on a top surface of the voltage regulator, (b) partially on the top of the voltage regulator and partially on a side adjacent to the voltage regulator, and (c) on a side adjacent to the voltage regulator. The voltage regulator phase output terminal may include a metal slug comprising a thermal mass.

According to this example, the metal slug may include various materials such as copper, a copper alloy, aluminum, and an aluminum alloy, and the like. The inductor segment may overlap a portion of the voltage regulator phase output terminal or an entirety of the voltage regulator phase output terminal. The inductor segment may be U-shaped (as shown in FIG. 3, as an upside-down “U”, for example) and extends continuously from an underside portion of the inductor module to the printed circuit board. In this manner, a large portion of the surface of the U-shaped inductor segment may be exposed to the top and side surface allowing radiation and convection to dissipate heat. The inductor segment first end (primary portion 302) may be soldered to the voltage regulator output phase terminal and inductor segment second end may be soldered to the printed circuit board conductive trace. In this manner, a stable, durable and thermally conductive path may be formed starting at a heat generating portion of the voltage regulator (e.g., MOSFETs), to the first end of the inductor segment, to an interior portion of the inductor module contacting the inductor segment, and to the printed circuit board.

According to this example, the electronic system may further include a power stage including a pair of metal oxide semiconductor field effect (MOSFET) transistors arranged in series between a voltage input (Vin) and a ground, the pair of MOSFET transistors having an intermediate node between them that is coupled to the voltage regulator phase output terminal (PH); and a driver circuit coupled to the power stage and configured to control operation of the pair of transistors to drive power from the voltage input to the voltage output. The electronic system may further include a controller (controller 102) coupled to the driver circuit (driver ICs 112, 114, 122, 124) and configured to execute a sequence of instructions or to implement a hardware algorithm to operate the driver circuit. In this manner, suitable instructions may be downloaded from a computer to the controller, a hardware configuration may be arranged to control operation of the driver circuit, or a combination of instructions and hardware may be utilized. The inductor segment may be a first inductor segment (primary portion 302), and the electronic system may further include a second inductor segment (secondary portion 304)configured to surround the portion of the inductor core wrapped around by the first inductor segment. Thus, the second inductor segment may be disposed between the first inductor segment and the inductor core. The first inductor segment and the second inductor segment may form a transformer with the inductor core.

According to another example, an electronic system may be described as a dual Trans-Inductor Voltage Regulator (Dual TLVR) and may include a printed circuit board having a first conductive trace and a second conductive trace; a first voltage regulator (PS1) disposed on the printed circuit board and having a first voltage regulator phase output terminal (Phase 1) that is accessible on a top surface of the first voltage regulator; a second voltage regulator (PS2) disposed on the printed circuit board and having a second voltage regulator phase output terminal (Phase 2) that is accessible on a top surface of the second voltage regulator; and an inductor module coupled with the first voltage regulator and the second voltage regulator and spanning at least a portion of a first top surface portion of the first voltage regulator and a second top surface portion of the second voltage regulator, the inductor module having an inductor core (e.g., a common inductor core) and an inductor segment (e.g., a common inductor segment) having a first end (primary portion 302) and a second end (secondary portion 304). Alternatively, the inductor core may be separated and the inductor segment may be separated, in various combinations.

The inductor segment first end may be connected to the first voltage regulator phase output terminal and the second voltage regulator phase output terminal. The inductor segment second end may be connected to the printed circuit board conductive trace. As described above, the connections between the inductor segment and the phase out terminals and the printed circuit board may be made by soldering. The inductor segment may be configured to pass through and wrap around at least a portion of the inductor core. The first voltage regulator and the second voltage regulator may be configured to transfer heat through the first voltage regulator phase output terminal and the second voltage regulator phase output terminal to the inductor segment and inductor module. The output inductor may be shared between PS1 and PS2 and where the inductor segment and both phase output terminals may be soldered to the printed circuit board (e.g., three solder joints, as shown in FIG. 3). Alternatively, the output inductor may be separated between PS1 and PS2 and where two inductor segments and both phase output terminals may be soldered to the printed circuit board (e.g., four solder joints, not shown). In this latter example, thermal performance of the separated inductors may be less than the thermal performance of the shared inductor example. Multiple dual TLVR modules may be cascaded together to increase drive strength between Vin and Vout, for example. A dual TLVR1 module (module 110) may include a first voltage regulator SPS1 with a first phase output terminal PH1 and a second voltage regulator PSN-1 with a second phase output terminal PH2. A second dual TLVR2 module (module 120) may include a third voltage regulator SPS3 with a third phase output terminal PH3 and a fourth voltage regulator PSN with a fourth phase output terminal PH4. This cascading may continue so that a last dual TLVR module may include an N-1th voltage regulator SPSN-1 which may include a N-1th phase output terminal PHN-1 and an Nth voltage regulator SPSN with an Nth phase output terminal PHN.

According to this example, the first conductive trace may have a first conductive trace first end and a first conductive trace second end. The first conductive trace second end may be disposed under a bottom portion of the first voltage regulator so that the first inductor segment and the first conductive trace surround at least an end portion of the first voltage regulator. The second conductive trace may have a second conductive trace first end and a second conductive trace second end. The second conductive trace second end may be disposed under a bottom portion of the second voltage regulator so that the second inductor segment and the second conductive trace surround at least an end portion of the second voltage regulator. The inductor core may be disposed (a) entirely on a top surface of the first voltage regulator and a top surface of the second voltage regulator, (b) partially on the top of the first voltage regulator and partially on the top of the second voltage regulator, or (c) on a side adjacent to the first voltage regulator and the second voltage regulator. At least one of the first voltage regulator phase output terminal and the second voltage regulator phase output terminal may include a metal slug comprising a thermal mass. Both the first voltage regulator phase output terminal and the second voltage regulator phase output terminal may include a metal slug comprising a thermal mass where each thermal mass may have different properties based on the expected power dissipation requirements of each voltage regulator. The metal slug may include copper, a copper alloy, aluminum, or an aluminum alloy, and the like. Other metal materials having similar thermal and electrical properties may also be used. The first inductor segment may overlap a portion of the first voltage regulator phase output terminal or an entirety of the first voltage regulator phase output terminal. The inductor segment may be U-shaped and may extends continuously from an underside portion of the inductor module to the printed circuit board. The inductor segment first end may be soldered to the voltage regulator output phase terminal and the inductor segment second end may be soldered to the printed circuit board conductive trace.

According to this example, the electronic system may further include a first power stage including a first pair of metal oxide semiconductor field effect (MOSFET) transistors arranged in series between a voltage input (Vin) and a ground, the first pair of MOSFET transistors having a first intermediate node between them that is coupled to the first voltage regulator phase output terminal (PH1); a first driver circuit (driver IC) coupled to the first power stage and configured to control operation of the first pair of transistors to drive power from the voltage input to the voltage output; a second power stage including a second pair of metal oxide semiconductor field effect transistors arranged in series between the voltage input (Vin) and the ground, the second pair of MOSFET transistors having a second intermediate node between them that is coupled to the second voltage regulator phase output terminal (PH2); and a second driver circuit coupled to the second power stage and configured to control operation of the second pair of transistors to drive power from the voltage input to the voltage output. The electronic system may further include a controller (controller 102) coupled to the first driver circuit and the second driver circuit. The controller may be configured to execute a sequence of instructions or a hardware algorithm to operate the first driver circuit and the second driver circuit. The electronic system may further include a third inductor segment configured to surround at the portion of the inductor core wrapped around by the first inductor segment. The third inductor segment may be disposed between the first inductor segment and the inductor core. The first inductor segment and the third inductor segment may form a first transformer with the inductor core, and a fourth inductor segment configured to surround at the portion of the inductor core wrapped around by the second inductor segment. The fourth inductor segment may be disposed between the second inductor segment and the inductor core. The second inductor segment and the fourth inductor segment may form a second transformer with the inductor core. The second inductor segment leads may be soldered to the printed circuit board.

As described above, a power stage may be configured to provide electrical power from a power source, such as a power adapter, a wall adapter, or a battery. The output (Vout) of a voltage regulator (or dual voltage regulators) may be applied to an electronic device, such as a computer, a laptop, or other portable electronic device. During operation, the MOSFET transistors may consume significant power which may require heat dissipation to maintain system reliability and prolong component life. The thermal mass of the copper slug, for example, may provide some equalization of temperatures due to transitory power demands on the one or more voltage regulators. While various embodiments are shown, these should not be considered limiting.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The disclosed embodiments of the present invention have been presented for purposes of illustration and description but are not intended to be exhaustive or limited to the invention in the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

1. An electronic system comprising:
a printed circuit board having a conductive trace that is coupled to a voltage output;
a voltage regulator disposed on the printed circuit board and having a voltage regulator phase output terminal that is accessible on a top surface of the voltage regulator; and
an inductor module coupled with the voltage regulator, the inductor module having an inductor core and an inductor segment having a first end and a second end, the inductor segment first end connected to the voltage regulator phase output terminal, the inductor segment second end connected to the printed circuit board conductive trace, the inductor segment configured to pass through and wrap around at least a portion of the inductor core, the voltage regulator configured to transfer heat through the voltage regulator phase output terminal to the inductor segment and inductor module.

2. The electronic system of claim 1, wherein the conductive trace has a conductive trace first end and a conductive trace second end, the conductive trace second end is disposed under a bottom portion of the voltage regulator so that the inductor segment and the conductive trace surround at least an end portion of the voltage regulator.

3. The electronic system of claim 1, wherein the inductor core is disposed one of:
(a) entirely on a top surface of the voltage regulator,
(b) partially on the top of the voltage regulator and partially on a side adjacent to the voltage regulator, and
(c) on a side adjacent to the voltage regulator.

4. The electronic system of claim 1, wherein the voltage regulator phase output terminal includes a metal slug comprising a thermal mass.

5. The electronic system of claim 1, wherein the inductor segment overlaps one of a portion of the voltage regulator phase output terminal and an entirety of the voltage regulator phase output terminal.

6. The electronic system of claim 1, wherein the inductor segment is U-shaped and extends continuously from an underside portion of the inductor module to the printed circuit board.

7. The electronic system of claim 6, wherein the inductor segment first end is soldered to the voltage regulator output phase terminal and the inductor segment second end is soldered to the printed circuit board conductive trace.

8. The electronic system of claim 1, further comprising:
a power stage including a pair of metal oxide semiconductor field effect (MOSFET) transistors arranged in series between a voltage input and a ground, the pair of MOSFET transistors having an intermediate node between them that is coupled to the voltage regulator phase output terminal; and
a driver circuit coupled to the power stage and configured to control operation of the pair of transistors to drive power from the voltage input to the voltage output.

9. The electronic system of claim 8 further comprising:
a controller coupled to the driver circuit and configured to execute at least one of a sequence of instructions and a hardware algorithm to operate the driver circuit.

10. The electronic system of claim 1, wherein the inductor segment is a first inductor segment, the electronic system further comprising a second inductor segment configured to surround the portion of the inductor core wrapped around by the first inductor segment, the second inductor segment disposed between the first inductor segment and the inductor core, the first inductor segment and the second inductor segment forming a transformer with the inductor core.

11. An electronic system comprising:
a printed circuit board having a first conductive trace and a second conductive trace;
a first voltage regulator disposed on the printed circuit board and having a first voltage regulator phase output terminal that is accessible on a top surface of the first voltage regulator;
a second voltage regulator disposed on the printed circuit board and having a second voltage regulator phase output terminal that is accessible on a top surface of the second voltage regulator; and
an inductor module coupled with the first voltage regulator and the second voltage regulator and spanning at least a portion of a first top surface portion of the first voltage regulator and a second top surface portion of the second voltage regulator, the inductor module having an inductor core and an inductor segment having a first end and a second end, the inductor segment first end connected to the first voltage regulator phase output terminal and the second voltage regulator phase output terminal, the inductor segment second end connected to the printed circuit board conductive trace, the inductor segment configured to pass through and wrap around at least a portion of the inductor core, the first voltage regulator and the second voltage regulator configured to transfer heat through the first voltage regulator phase output terminal and the second voltage regulator phase output terminal to the inductor segment and inductor module.

12. The electronic system of claim 11, wherein the first conductive trace has a first conductive trace first end and a first conductive trace second end, the first conductive trace second end is disposed under a bottom portion of the first voltage regulator so that the first inductor segment and the first conductive trace surround at least an end portion of the first voltage regulator, and wherein the second conductive trace has a second conductive trace first end and a second conductive trace second end, the second conductive trace second end is disposed under a bottom portion of the second voltage regulator so that the second inductor segment and the second conductive trace surround at least an end portion of the second voltage regulator.

13. The electronic system of claim 11, wherein the inductor core is disposed on one of:
(a) entirely on a top surface of the first voltage regulator and a top surface of the second voltage regulator,
(b) partially on the top of the first voltage regulator and partially on the top of the second voltage regulator, and
(c) on a side adjacent to the first voltage regulator and the second voltage regulator.

14. The electronic system of claim 11, wherein at least one of the first voltage regulator phase output terminal and the second voltage regulator phase output terminal include a metal slug comprising a thermal mass.

15. The electronic system of claim 11, wherein the inductor segment is U-shaped and extends continuously from an underside portion of the inductor module to the printed circuit board.

16. The electronic system of claim 11, wherein the inductor segment first end is soldered to the voltage regulator output phase terminal and to inductor segment second end is soldered to the printed circuit board conductive trace.

17. The electronic system of claim 11, further comprising:
a first power stage including a first pair of metal oxide semiconductor field effect (MOSFET) transistors arranged in series between a voltage input and a ground, the first pair of MOSFET transistors having a first intermediate node between them that is coupled to the first voltage regulator phase output terminal;
a first driver circuit coupled to the first power stage and configured to control operation of the first pair of transistors to drive power from the voltage input to the voltage output;
a second power stage including a second pair of metal oxide semiconductor field effect transistors arranged in series between the voltage input and the ground, the second pair of MOSFET transistors having a second intermediate node between them that is coupled to the second voltage regulator phase output terminal; and
a second driver circuit coupled to the second power stage and configured to control operation of the second pair of transistors to drive power from the voltage input to the voltage output.

18. The electronic system of claim 17 further comprising:
a controller coupled to the first driver circuit and the second driver circuit, the controller being configured to execute a sequence of instructions to operate the first driver circuit and the second driver circuit.

19. The electronic system of claim 11 further comprising:
a third inductor segment configured to surround at the portion of the inductor core wrapped around by the first inductor segment, the third inductor segment disposed between the first inductor segment and the inductor core, the first inductor segment and the third inductor segment forming a first transformer with the inductor core; and
a fourth inductor segment configured to surround at the portion of the inductor core wrapped around by the second inductor segment, the fourth inductor segment disposed between the second inductor segment and the inductor core, the second inductor segment and the fourth inductor segment forming a second transformer with the inductor core.

20. (canceled)
